(19) United States
(12) Patent Application Publication
(10) Pub. No.: US 2019/0034272 A1
(43) Pub. Date: Jan. 31, 2019

(54) UTILIZING CONCENTRIC STORAGE POOLS IN A DISPERSED STORAGE NETWORK

(71) Applicant: International Business Machines Corporation, Armonk, NY (US)

(72) Inventors: Jason K. Resch, Chicago, IL (US); Wesley B. Leggette, Chicago, IL (US)

(21) Appl. No.: 16/149,667

(22) Filed: Oct. 2, 2018

Related U.S. Application Data
(63) Continuation-in-part of application No. 15/819,810, filed on Nov. 21, 2017.
Application No. 15/819,810 is a continuation-in-part of application No. 13/869,655, filed on Apr. 24, 2013.
(60) Provisional application No. 61/655,736, filed on Jun. 5, 2012.

(51) Int. Cl. G06F 11/10; G11C 29/52; G06F 3/06

(52) U.S. Cl. CPC G06F 11/1068; G11C 29/52; G06F 3/067; G06F 3/0659; G06F 3/0619

(57) ABSTRACT

A method for execution by a dispersed storage (DS) client module includes receiving data for storage. The data is stored as a plurality of sets of encoded data slices in an affiliated local storage pool of storage units. The data is stored as another plurality of sets of encoded data slices in an affiliated next level storage pool of storage units in response to receiving no modification for the data within a time period. A data retrieval request indicating the data is received from a requesting entity. It is determined whether the data is available from the affiliated local storage pool. The data from the affiliated next level storage pool in response to determining that the data is not available from the affiliated local storage pool. The data is stored in the affiliated local storage pool, and the data is sent to the requesting entity.

### CROSS-REFERENCE TO RELATED APPLICATIONS

The present U.S. Utility patent application claims priority pursuant to 35 U.S.C. § 120 as a continuation-in-part of U.S. Utility application Ser. No. 15/819,810, entitled “STORAGE VAULT TIERING AND DATA MIGRATION IN A DISTRIBUTED STORAGE NETWORK,” filed Nov. 21, 2017, which is a continuation-in-part of U.S. Utility application Ser. No. 13/869,655, entitled “UPDATING ACCESS CONTROL INFORMATION WITHIN A DISPERSED STORAGE UNIT,” filed Apr. 24, 2013, which claims priority pursuant to 35 U.S.C. § 119(e) to U.S. Provisional Application No. 61/655,736, entitled “STORING DATA IN A LAYERED DISTRIBUTED STORAGE AND TASK NETWORK”, filed Jun. 5, 2012, all of which are hereby incorporated herein by reference in their entirety and made part of the present U.S. Utility patent application for all purposes.

### STATEMENT REGARDING FEDERALLY SPONSORED RESEARCH OR DEVELOPMENT

Not applicable.

### INCORPORATION-BY-REFERENCE OF MATERIAL SUBMITTED ON A COMPACT DISC

Not applicable.

### BACKGROUND OF THE INVENTION

### Technical Field of the Invention

This invention relates generally to computer networks and more particularly to dispersing error encoded data.

### Description of Related Art

Computing devices are known to communicate data, process data, and/or store data. Such computing devices range from wireless smart phones, laptops, tablets, personal computers (PC), work stations, and video game devices, to data centers that support millions of web searches, stock trades, or on-line purchases every day. In general, a computing device includes a central processing unit (CPU), a memory system, user input/output interfaces, peripheral device interfaces, and an interconnecting bus structure.

As is further known, a computer may effectively extend its CPU by using “cloud computing” to perform one or more computing functions (e.g., a service, an application, an algorithm, an arithmetic logic function, etc.) on behalf of the computer. Further, for large services, applications, and/or functions, cloud computing may be performed by multiple cloud computing resources in a distributed manner to improve the response time for completion of the service, application, and/or function. For example, Hadoop is an open source software framework that supports distributed applications enabling application execution by thousands of computers.

In addition to cloud computing, a computer may use “cloud storage” as part of its memory system. As is known, cloud storage enables a user, via its computer, to store files, applications, etc. on an Internet storage system. The Internet storage system may include a RAID (redundant array of independent disks) system and/or a dispersed storage system that uses an error correction scheme to encode data for storage.

### BRIEF DESCRIPTION OF THE SEVERAL VIEWS OF THE DRAWING(S)

FIG. 1 is a schematic block diagram of an embodiment of a dispersed or distributed storage network (DSN) in accordance with the present invention;

FIG. 2 is a schematic block diagram of an embodiment of a computing core in accordance with the present invention;

FIG. 3 is a schematic block diagram of an example of dispersed storage error encoding of data in accordance with the present invention;

FIG. 4 is a schematic block diagram of a generic example of an error encoding function in accordance with the present invention;

FIG. 5 is a schematic block diagram of a specific example of an error encoding function in accordance with the present invention;

FIG. 6 is a schematic block diagram of an example of a slice name of an encoded data slice (EDS) in accordance with the present invention;

FIG. 7 is a schematic block diagram of an example of dispersed storage error decoding of data in accordance with the present invention;

FIG. 8 is a schematic block diagram of a generic example of an error decoding function in accordance with the present invention;

FIG. 9 is a schematic block diagram of an embodiment of a dispersed or distributed storage network (DSN) in accordance with the present invention;

FIG. 10A is a logic diagram of an example of a method of storing data in accordance with the present invention; and

FIG. 10B is a logic diagram of an example of a method of reading data in accordance with the present invention.

### DETAILED DESCRIPTION OF THE INVENTION

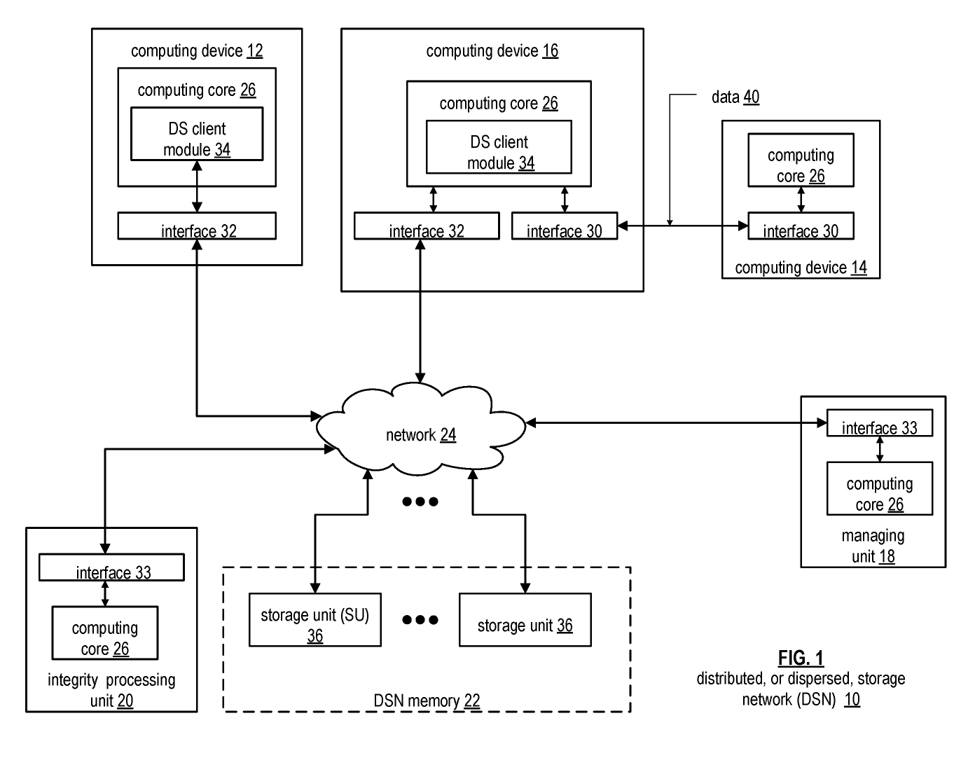

FIG. 1 is a schematic block diagram of an embodiment of a dispersed, or distributed, storage network (DSN) 10 that includes a plurality of computing devices 12-16, a managing unit 18, an integrity processing unit 20, and a DSN memory 22. The components of the DSN 10 are coupled to a network 24, which may include one or more wireless and/or wire lined communication systems; one or more non-public intranet systems and/or public internet systems; and/or one or more local area networks (LAN) and/or wide area networks (WAN).

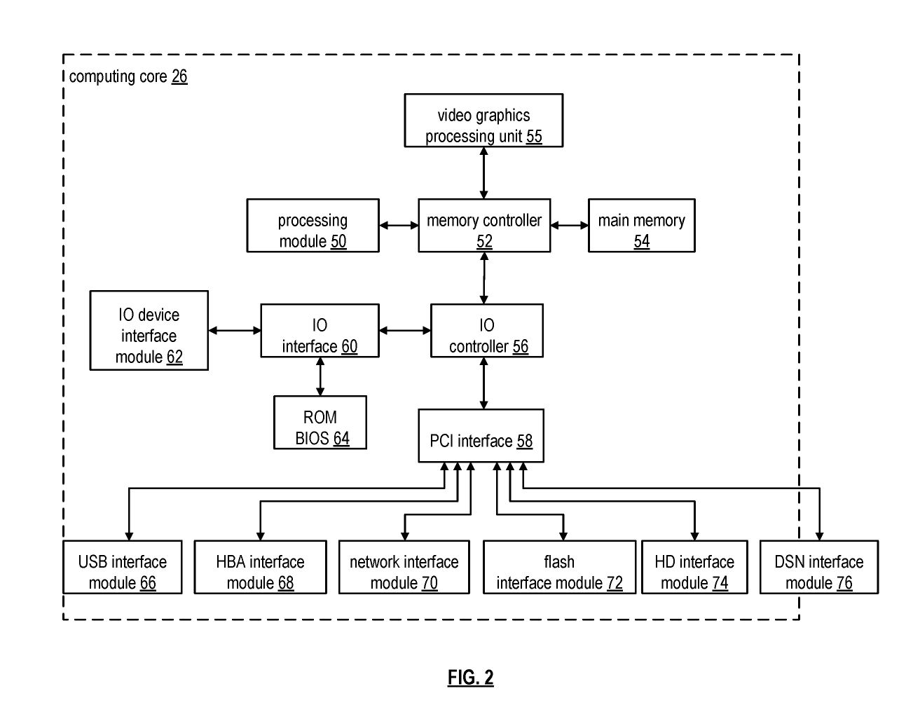

The DSN memory 22 includes a plurality of storage units 36 that may be located at geographically different sites (e.g., one in Chicago, one in Milwaukee, etc.), at a common site, or a combination thereof. For example, if the DSN memory 22 includes eight storage units 36, each storage unit is located at a different site. As another example, if the DSN memory 22 includes eight storage units 36, all eight storage units are located at the same site. As yet another example, if the DSN memory 22 includes eight storage units 36, a first pair of storage units are at a first common site, a second pair of storage units are at a second common site, a third pair of storage units are at a third common site, and a fourth pair of storage units are at a fourth common site. Note that a DSN memory 22 may include more or less than eight storage units 36. Further note that each storage unit 36 includes a computing core (as shown in FIG. 2, or components thereof) and a plurality of memory devices for storing dispersed error encoded data.

In various embodiments, each of the storage units operates as a distributed storage and task (DST) execution unit, and is operable to store dispersed error encoded data and/or to execute, in a distributed manner, one or more tasks on data. The tasks may be a simple function (e.g., a mathematical function, a logic function, an identify function, a find function, a search engine function, a replace function, etc.), a complex function (e.g., compression, human and/or computer language translation, text-to-voice conversion, voice-to-text conversion, etc.), multiple simple and/or complex functions, one or more algorithms, one or more applications, etc. Hereafter, a storage unit may be interchangeably referred to as a dispersed storage and task (DST) execution unit and a set of storage units may be interchangeably referred to as a set of DST execution units.

Each of the computing devices 12-16, the managing unit 18, and the integrity processing unit 20 include a computing core 26, which includes network interfaces 30-33. Computing devices 12-16 may each be a portable computing device and/or a fixed computing device. A portable computing device may be a social networking device, a gaming device, a cell phone, a smart phone, a digital assistant, a digital music player, a digital video player, a laptop computer, a handheld computer, a tablet, a video game controller, and/or any other portable device that includes a computing core. A fixed computing device may be a computer (PC), a computer server, a cable set-top box, a satellite receiver, a television set, a printer, a fax machine, home entertainment equipment, a video game console, and/or any type of home or office computing equipment. Note that each managing unit 18 and the integrity processing unit 20 may be separate computing devices, may be a common computing device, and/or may be integrated into one or more of the computing devices 12-16 and/or into one or more of the storage units 36. In various embodiments, computing devices 12-16 can include user devices and/or can be utilized by a requesting entity generating access requests, which can include requests to read or write data to storage units in the DSN.

Each interface 30, 32, and 33 includes software and hardware to support one or more communication links via the network 24 indirectly and/or directly. For example, interface 30 supports a communication link (e.g., wired, wireless, direct, via a LAN, via the network 24, etc.) between computing devices 14 and 16. As another example, interface 32 supports communication links (e.g., a wired connection, a wireless connection, a LAN connection, and/or any other type of connection to/from the network 24) between computing devices 12 & 16 and the DSN memory 22. As yet another example, interface 33 supports a communication link for each of the managing unit 18 and the integrity processing unit 20 to the network 24.

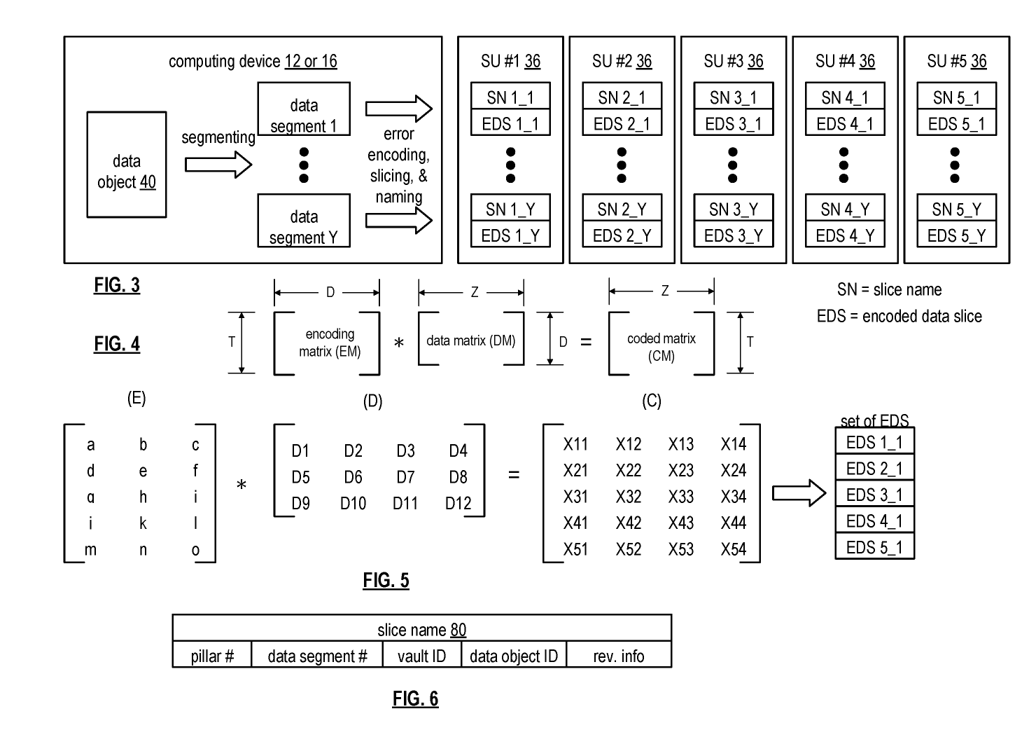

Computing devices 12 and 16 include a dispersed storage (DS) client module 34, which enables the computing device to dispersed storage error encode and decode data as subsequently described with reference to one or more of FIGS. 3-8. In this example embodiment, computing device 16 functions as a dispersed storage processing agent for computing device 14. In this role, computing device 16 dispersed storage error encodes and decodes data on behalf of computing device 14. With the use of dispersed storage error encoding and decoding, the DSN 10 is tolerant of a significant number of storage unit failures (the number of failures is based on parameters of the dispersed storage error encoding function) without loss of data and without the need for a redundant or backup copies of the data. Further, the DSN 10 stores data for an indefinite period of time without data loss and in a secure manner (e.g., the system is very resistant to unauthorized attempts at accessing the data).

In operation, the managing unit 18 performs DS management services. For example, the managing unit 18 establishes distributed data storage parameters (e.g., vault creation, distributed storage parameters, security parameters, billing information, user profile information, etc.) for computing devices 12-14 individually or as part of a group of user devices. As a specific example, the managing unit 18 coordinates creation of a vault (e.g., a virtual memory block associated with a portion of an overall namespace of the DSN) within the DSN memory 22 for a user device, a group of devices, or for public access and establishes per vault dispersed storage (DS) error encoding parameters for a vault. The managing unit 18 facilitates storage of DS error encoding parameters for each vault by updating registry information of the DSN 10, where the registry information may be stored in the DSN memory 22, a computing device 12-16, the managing unit 18, and/or the integrity processing unit 20.

The DSN managing unit 18 creates and stores user profile information (e.g., an access control list (ACL)) in local memory and/or within memory of the DSN memory 22. The user profile information includes authentication information, permissions, and/or the security parameters. The security parameters may include encryption/decryption scheme, one or more encryption keys, key generation scheme, and/or data encoding/decoding scheme.

The DSN managing unit 18 creates billing information for a particular user, a user group, a vault access, public vault access, etc. For instance, the DSN managing unit 18 tracks the number of times a user accesses a non-public vault and/or public vaults, which can be used to generate a per-access billing information. In another instance, the DSN managing unit 18 tracks the amount of data stored and/or retrieved by a user device and/or a user group, which can be used to generate a per-data-amount billing information.

As another example, the managing unit 18 performs network operations, network administration, and/or network maintenance. Network operations includes authenticating user data allocation requests (e.g., read and/or write requests), managing creation of vaults, establishing authentication credentials for user devices, adding/deleting components (e.g., user devices, storage units, and/or computing devices with a DS client module 34) to/from the DSN 10, and/or establishing authentication credentials for the storage units 36. Network administration includes monitoring devices and/or units for failures, maintaining vault information, determining device and/or unit activation status, determining device and/or unit loading, and/or determining any other system level operation that affects the performance level of the DSN 10. Network maintenance includes facilitating replacing, upgrading, repairing, and/or expanding a device and/or unit of the DSN 10.

The integrity processing unit 20 performs rebuilding of ‘bad’ or missing encoded data slices. At a high level, the integrity processing unit 20 performs rebuilding by periodically attempting to retrieve/list encoded data slices, and/or slice names of the encoded data slices, from the DSN memory 22. For retrieved encoded slices, they are checked for errors due to data corruption, outdated version, etc. If a slice includes an error, it is flagged as a ‘bad’ slice. For encoded data slices that were not received and/or not listed, they are flagged as missing slices. Bad and/or missing slices are subsequently rebuilt using other retrieved encoded data slices that are deemed to be good slices to produce rebuilt slices. The rebuilt slices are stored in the DSN memory 22.

FIG. 2 is a schematic block diagram of an embodiment of a computing core 26 that includes a processing module 50, a memory controller 52, main memory 54, a video graphics processing unit 55, an input/output (IO) controller 56, a peripheral component interconnect (PCI) interface 58, an 10 interface module 60, at least one IO device interface module 62, a read only memory (ROM) basic input output system (BIOS) 64, and one or more memory interface modules. The one or more memory interface module(s) includes one or more of a universal serial bus (USB) interface module 66, a host bus adapter (HBA) interface module 68, a network interface module 70, a flash interface module 72, a hard drive interface module 74, and a DSN interface module 76.

The DSN interface module 76 functions to mimic a conventional operating system (OS) file system interface (e.g., network file system (NFS), flash file system (FFS), disk file system (DFS), file transfer protocol (FTP), web-based distributed authoring and versioning (WebDAV), etc.) and/or a block memory interface (e.g., small computer system interface (SCSI), internet small computer system interface (iSCSI), etc.). The DSN interface module 76 and/or the network interface module 70 may function as one or more of the interface 30-33 of FIG. 1. Note that the IO device interface module 62 and/or the memory interface modules 66-76 may be collectively or individually referred to as IO ports.

FIG. 3 is a schematic block diagram of an example of dispersed storage error encoding of data. When a computing device 12 or 16 has data to store it disperse storage error encodes the data in accordance with a dispersed storage error encoding process based on dispersed storage error encoding parameters. Here, the computing device stores data object 40, which can include a file (e.g., text, video, audio, etc.), or other data arrangement. The dispersed storage error encoding parameters include an encoding function (e.g., information dispersal algorithm (IDA), Reed-Solomon, Cauchy Reed-Solomon, systematic encoding, non-systematic encoding, on-line codes, etc.), a data segmenting protocol (e.g., data segment size, fixed, variable, etc.), and per data segment encoding values. The per data segment encoding values include a total, or pillar width, number (T) of encoded data slices per encoding of a data segment i.e., in a set of encoded data slices); a decode threshold number (D) of encoded data slices of a set of encoded data slices that are needed to recover the data segment; a read threshold number (R) of encoded data slices to indicate a number of encoded data slices per set to be read from storage for decoding of the data segment; and/or a write threshold number (W) to indicate a number of encoded data slices per set that must be accurately stored before the encoded data segment is deemed to have been properly stored. The dispersed storage error encoding parameters may further include slicing information (e.g., the number of encoded data slices that will be created for each data segment) and/or slice security information (e.g., per encoded data slice encryption, compression, integrity checksum, etc.).

In the present example, Cauchy Reed-Solomon has been selected as the encoding function (a generic example is shown in FIG. 4 and a specific example is shown in FIG. 5); the data segmenting protocol is to divide the data object into fixed sized data segments; and the per data segment encoding values include: a pillar width of 5, a decode threshold of 3, a read threshold of 4, and a write threshold of 4. In accordance with the data segmenting protocol, the computing device 12 or 16 divides data object 40 into a plurality of fixed sized data segments (e.g., 1 through Y of a fixed size in range of Kilo-bytes to Tera-bytes or more). The number of data segments created is dependent of the size of the data and the data segmenting protocol.

The computing device 12 or 16 then disperse storage error encodes a data segment using the selected encoding function (e.g., Cauchy Reed-Solomon) to produce a set of encoded data slices. FIG. 4 illustrates a generic Cauchy Reed-Solomon encoding function, which includes an encoding matrix (EM), a data matrix (DM), and a coded matrix (CM). The size of the encoding matrix (EM) is dependent on the pillar width number (T) and the decode threshold number (D) of selected per data segment encoding values. To produce the data matrix (DM), the data segment is divided into a plurality of data blocks and the data blocks are arranged into D number of rows with Z data blocks per row. Note that Z is a function of the number of data blocks created from the data segment and the decode threshold number (D). The coded matrix is produced by matrix multiplying the data matrix by the encoding matrix.

FIG. 5 illustrates a specific example of Cauchy Reed-Solomon encoding with a pillar number (T) of five and decode threshold number of three. In this example, a first data segment is divided into twelve data blocks (D1-D12). The coded matrix includes five rows of coded data blocks, where the first row of X11-X14 corresponds to a first encoded data slice (EDS 1_1), the second row of X21-X24 corresponds to a second encoded data slice (EDS 2_1), the third row of X31-X34 corresponds to a third encoded data slice (EDS 3_1), the fourth row of X41-X44 corresponds to a fourth encoded data slice (EDS 4_1), and the fifth row of X51-X54 corresponds to a fifth encoded data slice (EDS 5_1). Note that the second number of the EDS designation corresponds to the data segment number.

Returning to the discussion of FIG. 3, the computing device also creates a slice name (SN) for each encoded data slice (EDS) in the set of encoded data slices. A typical format for a slice name 80 is shown in FIG. 6. As shown, the slice name (SN) 80 includes a pillar number of the encoded data slice (e.g., one of 1-T), a data segment number (e.g., one of 1-Y), a vault identifier (ID), a data object identifier (ID), and may further include revision level information of the encoded data slices. The slice name functions as, at least part of, a DSN address for the encoded data slice for storage and retrieval from the DSN memory 22.

As a result of encoding, the computing device 12 or 16 produces a plurality of sets of encoded data slices, which are provided with their respective slice names to the storage units for storage. As shown, the first set of encoded data slices includes EDS 1_1 through EDS 5_1 and the first set of slice names includes SN 1_1 through SN 5_1 and the last set of encoded data slices includes EDS 1_Y through EDS 5_Y and the last set of slice names includes SN 1_Y through SN 5_Y.

FIG. 7 is a schematic block diagram of an example of dispersed storage error decoding of a data object that was dispersed storage error encoded and stored in the example of FIG. 4. In this example, the computing device 12 or 16 retrieves from the storage units at least the decode threshold number of encoded data slices per data segment. As a specific example, the computing device retrieves a read threshold number of encoded data slices.

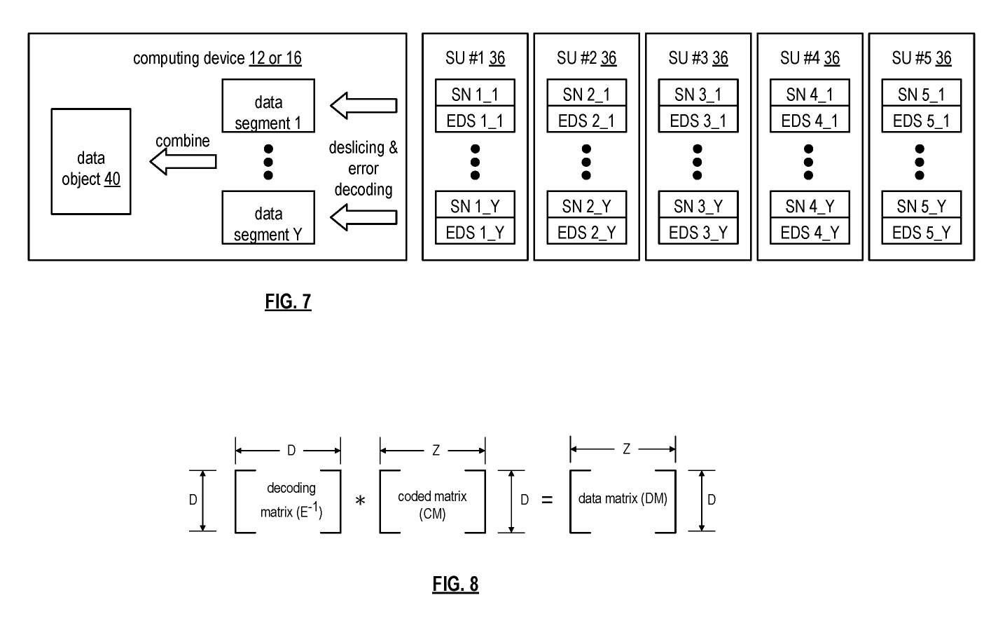

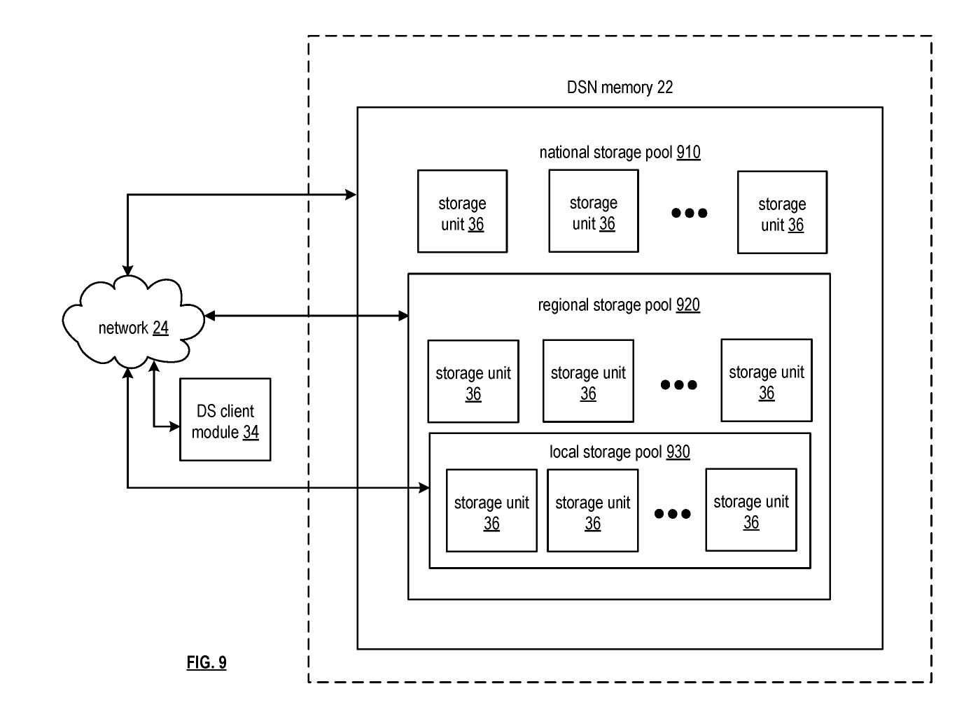

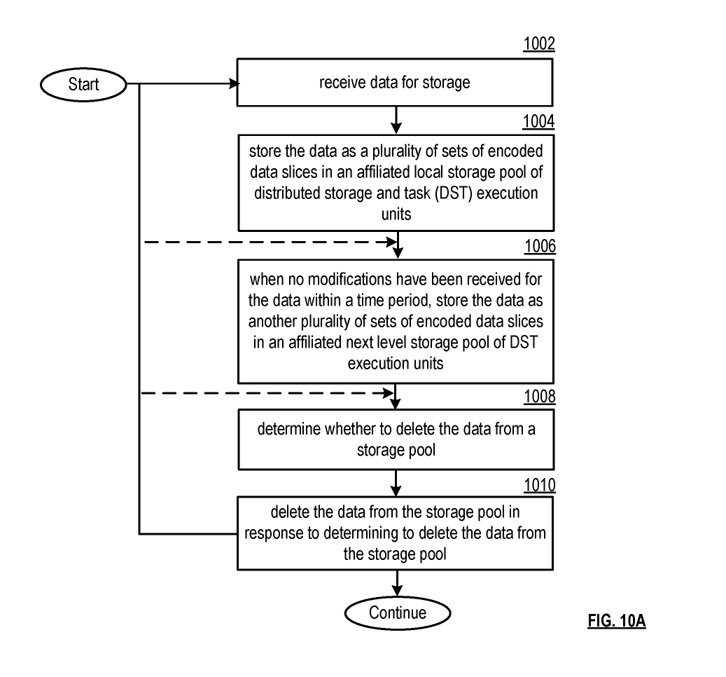

To recover a data segment from a decode threshold number of encoded data slices, the computing device uses a decoding function as shown in FIG. 8. As shown, the decoding function is essentially an inverse of the encoding function of FIG. 4. The coded matrix includes a decode threshold number of rows (e.g., three in this example) and the decoding matrix in an inversion of the encoding matrix that includes the corresponding rows of the coded matrix. For example, if the coded matrix includes rows 1, 2, and 4, the encoding matrix is reduced to rows 1, 2, and 4, and then inverted to produce the decoding matrix.

FIG. 9 is a schematic block diagram of an embodiment of a distributed computing system. The system includes a network 24 and DSN memory 22 of FIG. 1. As used herein, the DSN memory 22 can interchangeably be referred to as a DSTN module. The DSTN module includes a plurality of concentric storage pools. For example, a national storage pool 910 includes a regional storage pool 920 and a local storage pool 930. The regional storage pool includes the local storage pool. Each storage pool of the plurality of concentric storage pools includes a set of storage units 36 of FIG. 1. The set of storage units can be implemented as distributed storage and task (DST) execution modules, utilized to access at least one of slices and error coded slices. As used herein the storage units 36 will be interchangeably referred to as DST execution modules. Each storage pool of the plurality of concentric storage pools is operably coupled via the network 24 to the plurality of concentric storage pools to facilitate migrating slices and/or error coded slices (e.g., “slices”). The migrating slices may enable a more favorable match of a slice storage performance requirement and an actual slice storage performance when at least one storage pool of the plurality of concentric storage pools is associated with an actual slice storage performance level that is different than an actual slice storage performance level associated with at least one other storage pool.

Each storage pool can be associated with a target slice storage performance level. The target slice storage performance level can include one or more of an access latency level, an access bandwidth level, a cost level, a storage capacity level, a geographic affiliation, a security level, and an availability level. For example, the local storage pool can be associated with active storage requiring a target slice performance level that includes a lowest access latency performance level and an average reliability level. As another example, the national storage pool can be associated with inactive storage requiring a target slice performance level that includes allowing a highest access latency performance level and mandating a highest reliability level. As yet another example, the regional storage pool can be associated with near line storage requiring a target slice performance level including an average access latency performance level and an average reliability level.

A set of slices can be accessed in at least one storage pool of the plurality of concentric storage pools. For example, a set of slices are generated and initially stored in the plurality of DST execution units of the local storage pool such that frequent accessing of a set of slices may benefit from a storage performance level associated with the local storage pool. As time goes on a storage requirement may change. For example, a frequency of access requirement may lower as time goes on. As such, the set of slices can be transferred to a storage pool at their lines with a lowered frequency of access requirement. For example, the set of slices are transferred from the local storage pool to the regional storage pool. As time further goes on, a similar process can repeat such that the set of slices are transferred from the regional storage pool for the national storage pool. A similar process can be utilized in a reverse direction. For example, the set of slices can be transferred from the national storage pool to the regional storage pool when the frequency of access requirement increases. As time further goes on, the set of slices can be transferred from the regional storage pool to the local storage pool as the frequency of access requirement further increases.

Resources associated with a storage pool contained within another storage pool can be utilized for storage of slices with the storage pool. For example, any of the DST execution units of the local storage pool may be utilized in addition to DST execution units associated with the regional storage pool (e.g., and not the local storage pool) when storing a set of slices in the regional storage pool. Resources can be associated with multiple storage pools based on multiple associations. For example, a plurality of DST execution units associated with a first local storage pool can also be associated with a second local storage pool. As another example, a plurality of DST execution units associated with a regional storage pool and a second local storage pool may not be associated with the first local storage pool.

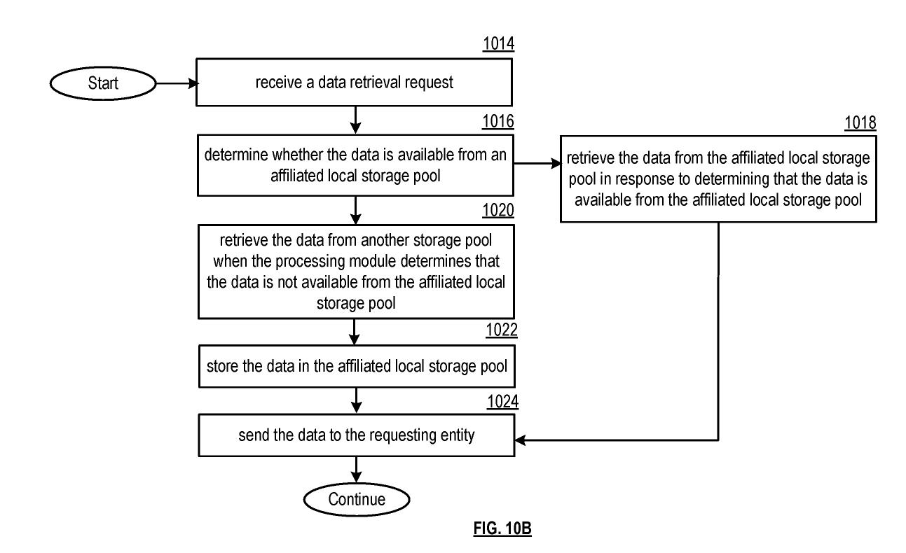

FIG. 10A is a flowchart illustrating an example of writing data. In particular, a method is presented for use in association with one or more functions and features described in conjunction with FIGS. 1-9, for execution by a dispersed storage (DS) client module 34 that includes a processor or via another processing system of a dispersed storage network that includes at least one processor and memory that stores instruction that configure the processor or processors to perform the steps described below.

The method begins at step 1002, where a processing system (e.g., of a distributed storage and task (DST) client module such as the DS client module 34 of FIG. 1) receives data for storage. The receiving can include receiving one or more of the data, a data identifier (ID), and/or a requesting entity ID. The method continues at step 1004, where the processing system stores the data as a plurality of sets of encoded data slices in an affiliated local storage pool of distributed storage and task (DST) execution units. The storing can include encoding the data utilizing a dispersed storage error coding function and in accordance with dispersed storage error coding function parameters associated with the local storage pool to produce the plurality of sets of encoded data slices, generating a plurality of sets of slice names associated with the plurality of sets of encoded data slices, generating a plurality of sets of write slice requests that includes the plurality of sets of encoded data slices and the plurality of sets of slice names, identifying a set of DST execution units of the local storage pool, initializing a frequency of access indicator corresponding to the data ID (e.g., a timestamp, a number of accesses=1), and/or outputting the plurality of sets of write slice requests to the identified set of DST execution units where each DST execution units of the identified set of DST execution units stores were more encoded data slices of the plurality of sets of encoded data slices.

When no modifications have been received for the data within a time period, the method continues at step 1006, where the processing system stores the data as another plurality of sets of encoded data slices in an affiliated next level storage pool of DST execution units. The processing system can indicate that no modifications have been received for the data within the time period when a real-time clock is greater than a timestamp of the frequency of access indicator corresponding to the data ID by a time period threshold. The storing the data can include at least one of generating and storing the other plurality of sets of encoded data slices and retrieving the plurality of sets of encoded data slices from the local storage pool and storing the plurality of sets of encoded data slices in the next level storage pool.

The generating and storing the other plurality of sets of encoded data slices can include obtaining the data, encoding the data utilizing the dispersed storage error coding function and in accordance with dispersed storage error coding function parameters of the next level storage pool to produce the other plurality of sets of encoded data slices, selecting a set of DST execution units of the next level storage pool, and/or outputting the other plurality of sets of encoded data slices to selected set of DST execution units of the next level storage pool. The obtaining can include retrieving the plurality of sets of encoded data slices from the local storage pool and/or decoding the plurality of sets of encoded data slices utilizing the dispersed storage error coding function and in accordance with the dispersed storage error coding parameters of the local storage pool to reproduce the data.

The method continues at step 1008 where the processing system determines whether to delete the data from a storage pool. The determination can be based on one or more of a storage pool identifier associated with storage of the data, a storage pool level (e.g., never delete from the national storage pool when utilizing the national storage pool as a long-term reliable backup), a value of the frequency of access indicator, a current timestamp, a storage pool memory utilization level, a time threshold, a storage pool memory utilization threshold, and/or a cost of storage estimate. For example, the processing system can indicate to delete the data from the local storage pool when the frequency of access indicator indicates that a time period since a last data access is greater than a time threshold. The method can loop back to at least one of the steps where the processing system receives more data, determines whether any modifications have been received to move the data to another storage level, and/or determines whether to delete the data when the processing system determines not to delete the data from the storage pool. The method continues to step 1010 when the processing system determines to delete the data from storage pool, which includes deleting the data from the storage pool. The deleting can include one or more of verifying that the data is currently stored in another higher-level storage pool and/or requesting deletion of the data from the storage pool when the data is verified to be stored in the other higher-level storage pool.

FIG. 10B is a flowchart illustrating an example of reading data. In particular, a method is presented for use in association with one or more functions and features described in conjunction with FIGS. 1-9, for execution by a dispersed storage (DS) client module 34 that includes a processor or via another processing system of a dispersed storage network that includes at least one processor and memory that stores instruction that configure the processor or processors to perform the steps described below. The dispersed storage (DS) client module 34 can perform some or all of the steps of FIG. 10B alternatively or in addition to some or all of the steps of FIG. 10A. For example, step 1014 of FIG. 10B can follow completion of step 1010 of FIG. 10A.

The method begins at step 1014, where a processing system (e.g., of a distributed storage and task (DST) client module such as DS client module 34) receives a data retrieval request. The receiving can include receiving one or more of a requesting entity identifier (ID), a data ID, a mandatory storage pool ID, and a preferred storage pool ID. The method continues at step 1016, where the processing system determines whether the data is available from an affiliated local storage pool. The determining can be based on at least one of outputting a read request, outputting a list request, outputting a list digest request, accessing a list, and/or receiving a response.

The method continues at step 1018 when the processing system determines that the data is available from the affiliated local storage pool. Step 1018 includes retrieving the data from the affiliated local storage pool. The retrieving can include generating a plurality of sets of read slice requests that include a plurality of sets of slice names associated with the data, outputting the plurality of sets of read slice requests to a set of DST execution units of the affiliated local storage pool, receiving a plurality of at least a decode threshold number of encoded data slices, and/or decoding the plurality of the at least the decode threshold number of encoded data slices to reproduce the data. The method branches to step 1024, where the processing system sends the data to the requesting entity.

When the processing system determines that the data is not available from the affiliated local storage pool, after completing step 1016, the method continues at step 1020, where the processing system retrieves the data from another storage pool. The retrieving can include identifying the other storage pool, retrieving the plurality of sets of encoded data slices, and/or decoding the plurality of sets of encoded data slices to reproduce the data. The identifying can be based on at least one of accessing a data to storage pool identifier list, sending a read request, sending a list request, sending a list digest request, and/or receiving a response. For example, the processing system can identify a higher-level storage pool that includes the data, retrieves the slices, and/or decodes the slices to reproduce the data. The method continues at step 1022, where the processing system stores the data in the affiliated local storage pool (e.g., since frequency of access has increased). The storing can include storing the plurality of sets of encoded data slices in the affiliated local storage pool and/or re-encoding the data to produce a second plurality of encoded data slices for storage in the affiliated local storage pool. The method continues at step 1024, where the processing system sends the data to the requesting entity.

In various embodiments, a non-transitory computer readable storage medium includes at least one memory section that stores operational instructions that, when executed by a processing system of a dispersed storage network (DSN) that includes a processor and a memory, causes the processing system to receive data for storage. The data is stored as a plurality of sets of encoded data slices in an affiliated local storage pool of storage units. The data is stored as another plurality of sets of encoded data slices in an affiliated next level storage pool of storage units in response to receiving no modification for the data within a time period. A data retrieval request indicating the data is received from a requesting entity. It is determined whether the data is available from the affiliated local storage pool. The data from the affiliated next level storage pool in response to determining that the data is not available from the affiliated local storage pool. The data is stored in the affiliated local storage pool, and the data is sent to the requesting entity.

In various embodiments, a data segment of the data is dispersed storage error encoded to produce a set of encoded data slices of the plurality of sets of encoded data slices. The set of encoded data slices is retrieved from the affiliated next level storage pool. The set of encoded data slices are dispersed storage error decoded to reproduce the data segment of the data to be sent to the requesting entity. In various embodiments deletion of the data from a storage pool is facilitated in response to determining to delete the data from the storage pool determining to delete the data from the storage pool. In various embodiments, the affiliated next level storage pool includes a plurality of local storage pools that includes the affiliated local storage pool. In various embodiments, another one of the plurality of local storage pools utilizes at least one of the storage units of the affiliated local storage pool.

In various embodiments, a high level storage pool includes a plurality of mid-level storage pools that includes the affiliated next level storage pool. In various embodiments, the data is stored as a second other plurality of sets of encoded data slices in the high level storage pool in response to receiving no modification for the data within a second time period that is longer than the time period. In various embodiments, the affiliated local storage pool is associated with active storage requiring a target slice performance level that includes a lowest access latency performance level and an average reliability level. The high level storage pool is associated with inactive storage requiring a target slice performance level that includes allowing a highest access latency performance level and mandating a highest reliability level, and the affiliated next level storage pool is associated with near line storage requiring a target slice performance level including an average access latency performance level and an average reliability level. In various embodiments, the target slice storage performance level includes a security level, and the data is further stored as the other plurality of sets of encoded data slices in the affiliated next level storage pool based on the security level of the data.

It is noted that terminologies as may be used herein such as bit stream, stream, signal sequence, etc. (or their equivalents) have been used interchangeably to describe digital information whose content corresponds to any of a number of desired types (e.g., data, video, speech, text, graphics, audio, etc. any of which may generally be referred to as ‘data’).

As may be used herein, the terms “substantially” and “approximately” provides an industry-accepted tolerance for its corresponding term and/or relativity between items. For some industries, an industry-accepted tolerance is less than one percent and, for other industries, the industry-accepted tolerance is 10 percent or more. Industry-accepted tolerances correspond to, but are not limited to, component values, integrated circuit process variations, temperature variations, rise and fall times, thermal noise, dimensions, signaling errors, dropped packets, temperatures, pressures, material compositions, and/or performance metrics. Within an industry, tolerance variances of accepted tolerances may be more or less than a percentage level (e.g., dimension tolerance of less than +/−1%).

As may also be used herein, the term(s) “configured to”, “operably coupled to”, “coupled to”, and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”.

As may even further be used herein, the term “configured to”, “operable to”, “coupled to”, or “operably coupled to” indicates that an item includes one or more of power connections, input(s), output(s), etc., to perform, when activated, one or more its corresponding functions and may further include inferred coupling to one or more other items. As may still further be used herein, the term “associated with”, includes direct and/or indirect coupling of separate items and/or one item being embedded within another item.

As may be used herein, the term “compares favorably”, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1. As may be used herein, the term “compares unfavorably”, indicates that a comparison between two or more items, signals, etc., fails to provide the desired relationship.

As may be used herein, one or more claims may include, in a specific form of this generic form, the phrase “at least one of a, b, and c” or of this generic form “at least one of a, b, or c”, with more or less elements than “a”, “b”, and “c”. In either phrasing, the phrases are to be interpreted identically. In particular, “at least one of a, b, and c” is equivalent to “at least one of a, b, or c” and shall mean a, b, and/or c. As an example, it means: “a” only, “b” only, “c” only, “a” and “b”, “a” and “c”, “b” and “c”, and/or “a”, “b”, and “c”.

As may also be used herein, the terms “processing system”, “processing module”, “processing circuit”, “processor”, and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, processing system, and/or processing unit may be, or further include, memory and/or an integrated memory element, which may be a single memory device, a plurality of memory devices, and/or embedded circuitry of another processing module, module, processing circuit, processing system, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, processing system, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, processing system, and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, processing system, and/or processing unit executes, hard coded and/or operational instructions corresponding to at least some of the steps and/or functions illustrated in one or more of the Figures. Such a memory device or memory element can be included in an article of manufacture.

One or more embodiments have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

In addition, a flow diagram may include a “start” and/or “continue” indication. The “start” and “continue” indications reflect that the steps presented can optionally be incorporated in or otherwise used in conjunction with other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

The one or more embodiments are used herein to illustrate one or more aspects, one or more features, one or more concepts, and/or one or more examples. A physical embodiment of an apparatus, an article of manufacture, a machine, and/or of a process may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

While the transistors in the above described figure(s) is/are shown as field effect transistors (FETs), as one of ordinary skill in the art will appreciate, the transistors may be implemented using any type of transistor structure including, but not limited to, bipolar, metal oxide semiconductor field effect transistors (MOSFET), N-well transistors, P-well transistors, enhancement mode, depletion mode, and zero voltage threshold (VT) transistors.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

The term “module” is used in the description of one or more of the embodiments. A module implements one or more functions via a device such as a processor or other processing device or other hardware that may include or operate in association with a memory that stores operational instructions. A module may operate independently and/or in conjunction with software and/or firmware. As also used herein, a module may contain one or more sub-modules, each of which may be one or more modules.

As may further be used herein, a computer readable memory includes one or more memory elements. A memory element may be a separate memory device, multiple memory devices, or a set of memory locations within a memory device. Such a memory device may be a read-only memory, random access memory, volatile memory, non-volatile memory, static memory, dynamic memory, flash memory, cache memory, and/or any device that stores digital information. The memory device may be in a form a solid-state memory, a hard drive memory, cloud memory, thumb drive, server memory, computing device memory, and/or other physical medium for storing digital information.

While particular combinations of various functions and features of the one or more embodiments have been expressly described herein, other combinations of these features and functions are likewise possible. The present disclosure is not limited by the particular examples disclosed herein and expressly incorporates these other combinations.

What is claimed is:

1. A method for execution by a dispersed storage and task (DST) client module that includes a processor, the method comprises:
receiving data for storage;
storing the data as a plurality of sets of encoded data slices in an affiliated local storage pool of storage units;
storing the data as another plurality of sets of encoded data slices in an affiliated next level storage pool of storage in response to receiving no modification for the data within a time period;
receiving a data retrieval request indicating the data from a requesting entity;
determining whether the data is available from the affiliated local storage pool;
retrieving the data from the affiliated next level storage pool in response to determining that the data is not available from the affiliated local storage pool;
storing the data in the affiliated local storage pool; and
sending the data to the requesting entity.

2. The method of claim 1, further comprising:
dispersed storage error encoding a data segment of the data to produce a set of encoded data slices of the plurality of sets of encoded data slices;
retrieving the set of encoded data slices from the affiliated next level storage pool; and
dispersed storage error decoding the set of encoded data slices to reproduce the data segment of the data to be sent to the requesting entity.

3. The method of claim 1, further comprising facilitating deletion of the data from a storage pool in response to determining to delete the data from the storage pool determining to delete the data from the storage pool.

4. The method of claim 1, wherein the affiliated next level storage pool includes a plurality of local storage pools that includes the affiliated local storage pool.

5. The method of claim 4, wherein another one of the plurality of local storage pools utilizes at least one of the storage units of the affiliated local storage pool.

6. The method of claim 1, wherein a high level storage pool includes a plurality of mid-level storage pools that includes the affiliated next level storage pool.

7. The method of claim 6, wherein the data is stored as a second other plurality of sets of encoded data slices in the high level storage pool in response to receiving no modification for the data within a second time period that is longer than the time period.

8. The method of claim 6, wherein the affiliated local storage pool is associated with active storage requiring a target slice performance level that includes a lowest access latency performance level and an average reliability level, wherein the high level storage pool is associated with inactive storage requiring a target slice performance level that includes allowing a highest access latency performance level and mandating a highest reliability level, and wherein the affiliated next level storage pool is associated with near line storage requiring a target slice performance level including an average access latency performance level and an average reliability level.

9. The method of claim 8, wherein the target slice storage performance level includes a security level, and wherein the data is further stored as the other plurality of sets of encoded data slices in the affiliated next level storage pool based on the security level of the data.

10. A processing system of a dispersed storage (DS) client module comprises:
at least one processor;
a memory that stores operational instructions, that when executed by the at least one processor cause the processing system to:
receive data for storage;
store the data as a plurality of sets of encoded data slices in an affiliated local storage pool of storage units;
store the data as another plurality of sets of encoded data slices in an affiliated next level storage pool of storage units in response to receiving no modification for the data within a time period;
receive a data retrieval request indicating the data from a requesting entity;
determine whether the data is available from the affiliated local storage pool;
retrieve the data from the affiliated next level storage pool in response to determining that the data is not available from the affiliated local storage pool;
store the data in the affiliated local storage pool; and
send the data to the requesting entity.

11. The processing system of claim 10, wherein operational instructions, when executed by the at least one processor, further cause the processing system to:
dispersed storage error encode a data segment of the data to produce a set of encoded data slices of the plurality of sets of encoded data slices;
retrieve the set of encoded data slices from the affiliated next level storage pool; and
dispersed storage error decode the set of encoded data slices to reproduce the data segment of the data to be sent to the requesting entity.

12. The processing system of claim 10, wherein operational instructions, when executed by the at least one processor, further cause the processing system to facilitate deletion of the data from a storage pool in response to determining to delete the data from the storage pool determining to delete the data from the storage pool.

13. The processing system of claim 10, wherein the affiliated next level storage pool includes a plurality of local storage pools that includes the affiliated local storage pool.

14. The processing system of claim 13, wherein another one of the plurality of local storage pools utilizes at least one of the storage units of the affiliated local storage pool.

15. The processing system of claim 10, wherein a high level storage pool includes a plurality of mid-level storage pools that includes the affiliated next level storage pool.

16. The processing system of claim 15, wherein the data is stored as a second other plurality of sets of encoded data slices in the high level storage pool in response to receiving no modification for the data within a second time period that is longer than the time period.

17. The processing system of claim 15, wherein the affiliated local storage pool is associated with active storage requiring a target slice performance level that includes a lowest access latency performance level and an average reliability level, wherein the high level storage pool is associated with inactive storage requiring a target slice performance level that includes allowing a highest access latency performance level and mandating a highest reliability level, and wherein the affiliated next level storage pool is associated with near line storage requiring a target slice performance level including an average access latency performance level and an average reliability level.

18. The processing system of claim 17, wherein the target slice storage performance level includes a security level, and wherein the data is further stored as the other plurality of sets of encoded data slices in the affiliated next level storage pool based on a security level of the data.

19. A computer readable storage medium comprises:
at least one memory section that stores operational instructions that, when executed by a processing system of a dispersed storage network (DSN) that includes a processor and a memory, causes the processing system to:
receive data for storage;
store the data as a plurality of sets of encoded data slices in an affiliated local storage pool of storage units;
store the data as another plurality of sets of encoded data slices in an affiliated next level storage pool of storage units in response to receiving no modification for the data within a time period;
receive a data retrieval request indicating the data from a requesting entity;
determine whether the data is available from the affiliated local storage pool;
retrieve the data from the affiliated next level storage pool in response to determining that the data is not available from the affiliated local storage pool;
store the data in the affiliated local storage pool; and
send the data to the requesting entity.

20. The computer readable storage medium of claim 19, wherein the operational instructions, when executed by the processing system, further cause the processing system to facilitate deletion of the data from a storage pool in response to determining to delete the data from the storage pool determining to delete the data from the storage pool.
